(19) United States
(12) Patent Application Publication
(10) Pub. No.: US 2008/0253167 A1
(43) Pub. Date: Oct. 16, 2008

(54) Integrated Circuit, Method of Operating an Integrated Circuit, Method of Manufacturing an Integrated Circuit, Active Element, Memory Module, and Computing System

(76) Inventor: Ralf Symanczyk, Tuntenhausen (DE)

Correspondence Address: SLATER & MATSIL, L.L.P., 17950 PRESTON ROAD, SUITE 1000, DALLAS, TX, 75252, US

(21) Appl. No.: 11/735,876

(22) Filed: Apr. 16, 2007

(51) Int. Cl. G11C 11/00; H01L 21/20; H01L 47/00

(52) U.S. Cl. 365/148; 257/2; 438/584; 257/E47.001; 257/E21.09

(57) ABSTRACT

According to one embodiment of the present invention, an active element includes a reactive electrode, an inert electrode and a solid electrolyte disposed between the reactive electrode and the inert electrode. The solid electrolyte has a negative differential resistance.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1a shows a cross-sectional view of a solid electrolyte memory cell set to a first memory state;

FIG. 1b shows a cross-sectional view of a solid electrolyte memory cell set to a second memory state;

FIG. 2a shows a cross-sectional view of an active element according to one embodiment of the present invention which is set to a first switching state;

FIG. 2b shows a cross-sectional view of the active element shown in FIG. 2a set to a second switching state;

FIG. 3 shows a cross-sectional view of an active element according to one embodiment of the present invention;

FIG. 4 shows a flow chart of a method of operating an active element according to one embodiment of the present invention;

FIG. 5 shows a flow chart of a method of manufacturing an active element according to one embodiment of the present invention;

FIG. 6 shows a flow chart of a method of manufacturing an active element according to one embodiment of the present invention;

FIG. 7 shows an integrated circuit according to one embodiment of the present invention;

FIG. 8 shows an integrated circuit according to one embodiment of the present invention;

FIG. 9 shows a schematic drawing illustrating a technical principle underlying an active element according to one embodiment of the present invention;

FIG. 10a shows a flow chart of a method of manufacturing an active element according to one embodiment of the present invention;

FIG. 10b shows a flow chart of a method of manufacturing an active element according to one embodiment of the present invention;

FIG. 11a shows a memory module according to one embodiment of the present invention;

FIG. 11b shows a memory module according to one embodiment of the present invention; and

FIG. 12 shows a computing system according to one embodiment of the present invention.

### DETAILED DESCRIPTION OF ILLUSTRATIVE EMBODIMENTS

According to one embodiment of the present invention, an integrated circuit is provided including an active element which includes a reactive electrode, an inert electrode and a solid electrolyte disposed between the reactive electrode and the inert electrode, wherein the solid electrolyte has a negative differential resistance.

According to one embodiment of the present invention, an active element is provided which includes a reactive electrode, an inert electrode and a solid electrolyte disposed between the reactive electrode and the inert electrode, wherein the solid electrolyte has a negative differential resistance.

According to one embodiment of the present invention, the solid electrolyte comprises permanent existing voids being at least partly filled with metallic material.

According to one embodiment of the present invention, the voids are arranged such that metallic material is driven out of the voids as soon as an external voltage is applied between the reactive electrode and the inert electrode, or as soon as an external voltage being applied between the reactive electrode and the inert electrode exceeds a corresponding driving voltage threshold value.

According to one embodiment of the present invention, the voids are arranged such that metallic material is driven out of the solid electrolyte or out of the reactive electrode and into the voids as soon as an external voltage applied between the reactive electrode and the inert electrode vanishes, or as soon as an external voltage applied between the reactive electrode and the inert electrode falls below a corresponding driving voltage threshold value.

According to one embodiment of the present invention, the external voltage used for driving the metallic material out of the voids ranges from 0.1V to 2V or ranges from 0.2V to 1V or ranges from 0.3V to 0.5V.

According to one embodiment of the present invention, the metallic material forms metallic clusters within the voids.

According to one embodiment of the present invention, the voids have diameters ranging from 5 nm to 1 μm or ranging from 10 nm to 100 nm.

According to one embodiment of the present invention, the metallic material and the reactive electrode include the same material or consist of the same material. This material may, for example, be Ag (silver) or Cu (copper). More generally, this material may be any metal or compound that can easily be dissolved and/or diffused into the solid electrolyte.

According to one embodiment of the present invention, the solid electrolyte includes or consists of chalcogenide, i.e., GeS, GeSe, or AgS or compounds.

According to one embodiment of the present invention, the reactive electrode includes or consists of silver or copper or compounds of these metals.

According to one embodiment of the present invention, the metallic material includes or consists of silver.

According to one embodiment of the present invention, a method of operating an integrated circuit including an active element is provided. The active element includes a reactive electrode, an inert electrode and a solid electrolyte disposed between the reactive electrode and the inert electrode, wherein the solid electrolyte has a negative differential resistance. The method includes: increasing the resistance of the active element by increasing the strength of an external voltage applied between the reactive electrode and the inert electrode, and/or decreasing the resistance of the active element by decreasing the strength of an external voltage applied between the reactive electrode and the inert electrode.

According to one embodiment of the present invention, a method of operating an active element is provided. The active element includes a reactive electrode, an inert electrode and a solid electrolyte disposed between the reactive electrode and the inert electrode, wherein the solid electrolyte has a negative differential resistance. The method includes: increasing the resistance of the active element by increasing the strength of an external voltage applied between the reactive electrode and the inert electrode, and/or decreasing the resistance of the active element by decreasing the strength of an external voltage applied between the reactive electrode and the inert electrode.

According to one embodiment of the present invention, in order to increase the resistance of the active element, metallic material is driven out of permanent existing voids of the solid electrolyte by increasing the strength of an external voltage applied between the reactive electrode and the inert electrode.

According to one embodiment of the present invention, in order to decrease the resistance of the active element, metallic material is driven into permanent existing voids of the solid electrolyte by decreasing the strength of an external voltage applied between the reactive electrode and the inert electrode.

According to one embodiment of the present invention, the external voltage used for driving the metallic material out of the voids ranges from 0.1V to 2V or ranges from 0.2V to 1V or ranges from 0.3V to 0.5V.

According to one embodiment of the present invention, the external voltage used for driving the metallic material into the voids ranges from 0V to 0.3V or ranges from 0V to 0.1V.

According to one embodiment of the present invention, a method of manufacturing an integrated circuit including an active element is provided, the method including: subjecting a composite structure to a thermal annealing process, the composite structure including a reactive electrode, an inert electrode and a solid electrolyte disposed between the reactive electrode and the inert electrode, wherein the thermal annealing process is carried out until the solid electrolyte has a negative differential resistance.

According to one embodiment of the present invention, a method of manufacturing an active element is provided, the method including: subjecting a composite structure to a thermal annealing process, the composite structure including a reactive electrode, an inert electrode and a solid electrolyte disposed between the reactive electrode and the inert electrode, wherein the thermal annealing process is carried out until the solid electrolyte has a negative differential resistance.

According to one embodiment of the present invention, the parameters of the thermal annealing process are chosen such that permanent existing voids are formed within the solid electrolyte, which are filled with metallic material which, due to the thermal annealing process, is driven out of the reactive electrode into the solid electrolyte.

According to one embodiment of the present invention, the thermal annealing process is carried out at temperatures of about 300° C. to 500° C. or at temperatures of about 350° C. to 450° C.

According to one embodiment of the present invention, the duration of the thermal annealing process is about 10 minutes to 2 hours or is about 30 minutes to 1 hour.

According to one embodiment of the present invention, a method of manufacturing an integrated circuit including an active element is provided. The method includes: applying a voltage between the reactive electrode and the inert electrode of a composite structure including a reactive electrode, an inert electrode and a solid electrolyte disposed between the reactive electrode and the inert electrode. The application of the voltage is carried out until the solid electrolyte has a negative differential resistance.

According to one embodiment of the present invention, a method of manufacturing an active element is provided. The method includes: applying a voltage between the reactive electrode and the inert electrode of a composite structure including a reactive electrode, an inert electrode and a solid electrolyte disposed between the reactive electrode and the inert electrode. The application of the voltage enables electrical current flowing through the active element and is carried out until the solid electrolyte has a negative differential resistance.

According to one embodiment of the present invention, the application of the voltage is carried out until permanent existing voids are formed within the solid electrolyte, which are filled with metallic material. The metallic material is driven by the current flow out of the reactive electrode into the solid electrolyte due to the application of the voltage.

According to one embodiment of the present invention, the application of the voltage is carried out at voltages above 0.3V with a current limitation of 10 μA to 1 mA or a limitation of 50 μA to 200 μA.

According to one embodiment of the present invention, a method of manufacturing an integrated circuit is provided, the integrated circuit including an active element including a reactive electrode, an inert electrode and a solid electrolyte disposed between the reactive electrode and the inert electrode, the method including: depositing the solid electrolyte using a co-sputtering process of solid electrolyte material and metallic material.

According to one embodiment of the present invention, after having carried out the depositing process, the solid electrolyte is subjected to an annealing process.

According to one embodiment of the present invention, a method of manufacturing an integrated circuit is provided, the integrated circuit including an active element including a reactive electrode, an inert electrode and a solid electrolyte disposed between the reactive electrode and the inert electrode, the method including: depositing the solid electrolyte by depositing a multi-layer stack including a plurality of layers including solid electrolyte material and a plurality of layers including metallic material, and subjecting the multi-layer stack to an annealing process.

According to one embodiment of the present invention, the annealing process is part of subsequent processing steps including normal thermal budget of standard semiconductor processing which effects the metallic material inside the solid electrolyte that leads to a negative differential resistance.

According to one embodiment of the present invention, the active element is a diode or a transistor.

According to one embodiment of the present invention, the integrated circuit includes an amplifier, a frequency converter or an oscillator.

According to one embodiment of the present invention, the integrated circuit is a logic circuit controlling a solid electrolyte memory device.

According to one embodiment of the present invention, the logic circuit is built on the same chip on which the memory device is arranged.

All embodiments of integrated circuits according to the present invention can be applied to the embodiments of the active elements according to the present invention.

According to one embodiment of the present invention, a memory module is provided including at least one integrated circuit according to one embodiment of the present invention and/or at least one active element according to one embodiment of the present invention.

According to one embodiment of the present invention, the memory module is stackable.

According to one embodiment of the present invention, new types of active elements are provided which enable to facilitate the manufacturing process of integrated circuits including the active elements.

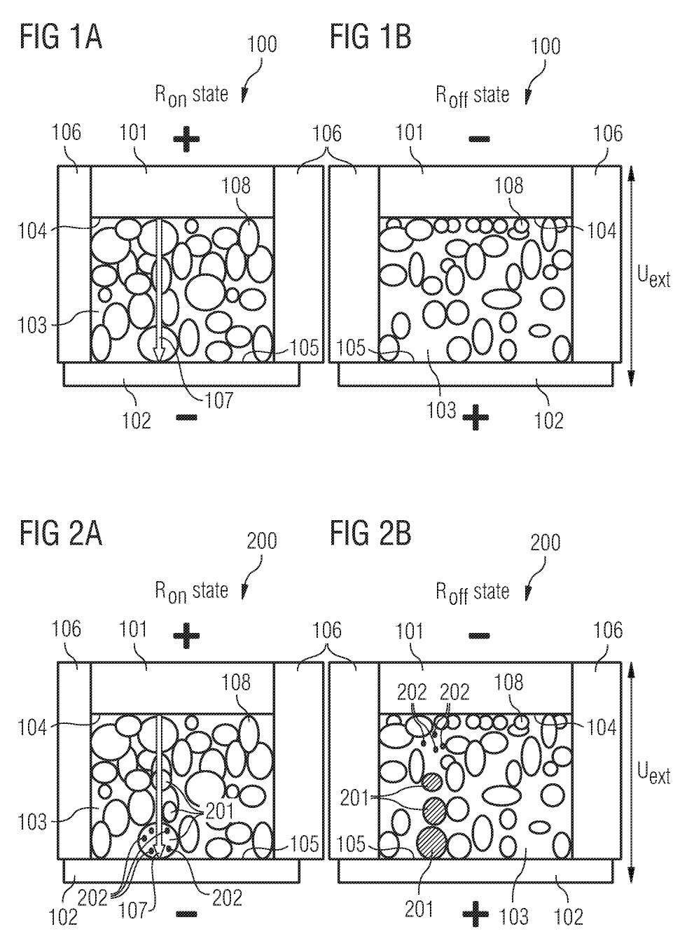

Since the embodiments of the present invention can be applied to programmable metallization cell devices (PMC) (e.g., solid electrolyte devices like CBRAM (conductive bridging random access memory) devices), in the following description, making reference to FIGS. 1a and 1b, a basic principle underlying embodiments of CBRAM devices will be explained.

As shown in FIG. 1a, a CBRAM cell 100 includes a first electrode 101 a second electrode 102, and a solid electrolyte block (in the following also referred to as ion conductor block) 103 which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may, for example, range between 5 nm and 500 nm. The thickness of the first electrode 101 may, for example, range between 10 nm and 100 nm. The thickness of the second electrode 102 may, for example, range between 5 nm and 500 nm, between 15 nm to 150 nm, or between 25 nm and 100 nm. It is to be understood that the present invention is not restricted to the above-mentioned materials and thicknesses.

In the context of this description, chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte. Furthermore, the ion conducting material can be made of a chalcogenide material containing metal ions, wherein the metal ions can be made of a metal, which is selected from a group consisting of silver, copper and zinc or of a combination or an alloy of these metals.

If a voltage as indicated in FIG. 1a is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1b (inverse voltage compared to the voltage applied in FIG. 1a), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107. After having applied the voltage/inverse voltage, the memory cell 100 remains within the corresponding defined switching state even if the voltage/inverse voltage has been removed.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may, for example, represent “0”, whereas a low resistance represents “1”, or vice versa. The memory status detection may also be carried out using sensing voltages.

FIGS. 2a and 2b show an active element 200 in a first switching state (FIG. 2a) and in a second switching state (FIG. 2b). The architecture of the active element 200 is the same as that of the memory cell 100 shown in FIGS. 1a and 1b. However, the active element 200 additionally includes permanent existing voids 201 which are at least partly filled with metallic material 202 in the first switching state (FIG. 2a), and which are completely empty of metallic material 202 in the second switching state (FIG. 2b). More generally, the first switching state shows an increased amount of metallic material 202 within its voids, compared to the second switching state. The voids 201 are located within the solid electrolyte block 103. The number of voids 201 within the solid electrolyte block 103 is arbitrary. For sake of simplicity, only three voids 201 are shown in FIGS. 2a and 2b. The voids 201 may be located at arbitrary positions within the solid electrolyte block 103.

The voids 201 effect that the solid electrolyte block 103 (and as a consequence, the whole active element 200) has a negative differential resistance (in the following description also referred to as “NDR”), i.e., a current flowing from the reactive electrode 101 to the inert electrode 102 through the solid electrolyte block 103 decreases in its strength if a voltage applied between the reactive electrode 101 and the inert electrode 102 increases in its strength. The negative differential resistance results from the voids 201. Metallic material is driven out of the voids as soon as an external voltage is applied between the reactive electrode 101 and the inert electrode 102, or as soon as an external voltage being applied between the reactive electrode 101 and the inert electrode 102 exceeds a corresponding driving voltage threshold value. In the same way, the voids 201 are arranged such that metallic material 202 is driven into the voids 201 as soon as an external voltage applied between the reactive electrode 101 and the inert electrode 102 is reduced to zero, or as soon as an external voltage applied between the reactive electrode 101 and the inert electrode 102 falls below a corresponding driving voltage threshold value.

A further difference between the active element 200 shown in FIGS. 2a and 2b and the memory cell 100 shown in FIGS. 1a and 1b is that an external voltage has to be applied between the reactive electrode 101 and the inert electrode 102 of the memory cell 100 in order to form a conductive bridge between the reactive electrode 101 and the inert electrode 102, whereas no external voltage has to be applied between the reactive electrode 101 and the inert electrode 102 of the active element 200 in order to form a conductive bridge between the reactive electrode 101 and the inert electrode 102. In other words, the conductive path 107 is automatically formed as soon as no external voltage is applied between the reactive electrode 101 and the inert electrode 102 of the active element 200; an external voltage has only to be applied between the reactive electrode 101 and the inert electrode 102 of the active element 200 if the conductive path 107 has to be erased (FIG. 2b). That is, the metallic material 202 “automatically” is driven into the voids 201 (and thus forms the conductive path 107) if no external voltage is applied between the reactive electrode 101 and the inert electrode 102. An external voltage is only needed if the metallic material 202 has to be driven out of the voids 201 into the solid electrolyte block 103. In other words, the voids 201 are “automatically” filled with metallic material 202 as soon as the active element is free of external influences, e.g., if no external voltage is applied between the reactive electrode 101 and the inert electrode 102.

FIGS. 2a and 2b show the case where the conductive path 107 is formed as soon as no external voltage is applied between the reactive electrode 101 and the inert electrode 102. However, the invention is not restricted to this. More generally, the conductive path 107 is formed if the external voltage applied between the reactive electrode 101 and the inert electrode 102 is lower in the first switching state (FIG. 2a) than in the second switching state (FIG. 2b). In this way, a negative differential resistance is obtained.

The external voltage used for driving the metallic material out of the voids may, for example, range from 0.1V to 2V or range from 0.2V to 1V or range from 0.3V to 0.5V.

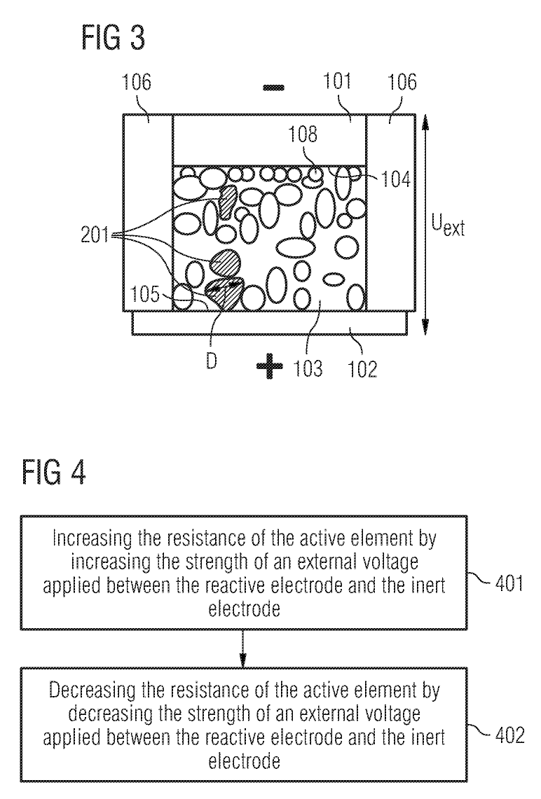

According to one embodiment of the present invention, the voids 201 have diameters D ranging from 5 nm to 1 μm or ranging from 10 nm to 100 nm, as shown in FIG. 3.

According to one embodiment of the present invention, the metallic material 202 forms metallic clusters within the voids 201. In this way, it is ensured that the metallic material 202 can be driven out of the voids 201 as soon as an external voltage of sufficient strength is applied between the reactive electrode 101 and the inert electrode 102. The metallic material may “condensate” within the voids also in other ways than in clusters.

According to one embodiment of the present invention, the metallic material 202 in the reactive electrode 101 includes the same material or consists of the same material, for example, silver (Ag).

According to one embodiment of the present invention, the solid electrolyte block 103 includes chalcogenide or consists of chalcogenide.

FIG. 4 shows a method of operating an active element (for example the active element 200 shown in FIGS. 2a and 2b) according to one embodiment of the present invention.

In a first process 401, the resistance of the active element is increased by increasing the strength of an external voltage applied between the reactive electrode and the inert electrode.

In a second process 402, the resistance of the active element is decreased by decreasing the strength of an external voltage applied between the reactive electrode and the inert electrode.

As an example, the method described above is applied to the active element 200 shown in FIGS. 2a and 2b. FIG. 2a shows the case where the resistance of the active element 200 is decreased since no external voltage is applied between the reactive electrode 101 and the inert electrode 102. FIG. 2b shows the case where the resistance of the active element 200 is increased, since, compared to FIG. 2a, the strength of an external voltage applied between the reactive electrode 101 and the inert electrode 102 is increased. In order to increase the resistance of the active element 200, metallic material 202 is driven out of the permanent existing voids of the solid electrolyte block 103 by increasing the strength of an external voltage applied between the reactive electrode 101 and the inert electrode 102. In order to decrease the resistance of the active element 200, metallic material is driven into the permanent existing voids 201 of the solid electrolyte block 103 by decreasing the strength of an external voltage applied between the reactive electrode 101 and the inert electrode 102. The external voltage used for driving the metallic material out of the voids may, for example, range from 0.1V to 2V or range from 0.2V to 1V or range from 0.3V to 0.5V. The external voltage used for driving the metallic material 202 into the voids 201 may, for example, range from 0V to 0.3V or range from 0V to 0.1V.

FIG. 5 shows a method of manufacturing an active element according to one embodiment of the present invention. In a first process 501, a composite structure is subjected to a thermal annealing process, wherein the composite structure includes a reactive electrode, an inert electrode, and a solid electrolyte disposed between the reactive electrode and the inert electrode. In a second process 502, it is determined whether the solid electrolyte, due to the thermal annealing process, already has a negative differential resistance. If the solid electrolyte already has a negative differential resistance, the method is terminated in a third process 503. Otherwise, the first process 501 is repeated.

As an example, the method described above is applied to the active element 200 shown in FIGS. 2a and 2b. The active element 200 shown in FIGS. 2a and 2b may initially not show a negative differential resistance (i.e., not contain voids 201). In order to create the negative differential resistance, the composite structure including the reactive electrode 101, the solid electrolyte block 103 and the inert electrode 102 may be annealed such that the solid electrolyte shows a negative differential resistance after having carried out the annealing process. In order to generate the negative differential resistance of the solid electrolyte block 103, the parameters of the thermal annealing process may be chosen such that permanent existing voids 201 are formed within the solid electrolyte block 103 which are filled with metallic material 202 which, due to the thermal annealing process, are driven out of the reactive electrode 101 into the solid electrolyte block 103. The thermal annealing process may, for example, be carried out at temperatures of about 300° C. to 500° C. or at temperatures of about 350° C. to 450° C. The duration of the thermal annealing process may, for example, be about 10 minutes to 2 hours or be about 30 minutes to 1 hour.

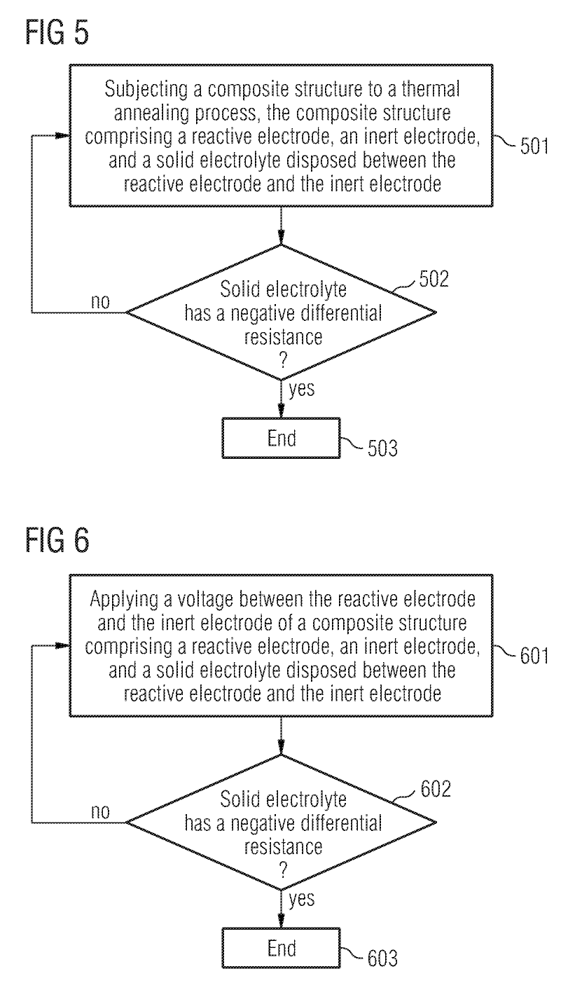

FIG. 6 shows a method of manufacturing an active element according to one embodiment of the present invention. In a first process 601, a voltage is applied between the reactive electrode and the inert electrode of a composite structure including a reactive electrode, an inert electrode and a solid electrolyte disposed between the reactive electrode and the inert electrode. In a second process 602, it is determined whether the solid electrolyte has a negative differential resistance. If the solid electrolyte has a negative differential resistance, the method is terminated in a third process 603. Otherwise, the method returns to the first process 601.

As an example, the method described above is applied to the active element 200 shown in FIGS. 2a and 2b: The active element 200 shown in FIGS. 2a and 2b may be subjected to an external voltage applied between the reactive electrode 101 and the inert electrode 102 producing a current flow through the active element 200. In order to generate the negative differential resistance, the application of the external voltage may be carried out until permanent existing voids 201 are formed within the solid electrolyte block 103 which are filled with metallic material, which, due to the application of the voltage, is driven out of the reactive electrode 101 into the solid electrolyte block 103. The external voltage applied may, for example, be a voltage above 0.3V with a current limitation of 10 μA to 11 mA or a limitation of 50 μA to 200 μA.

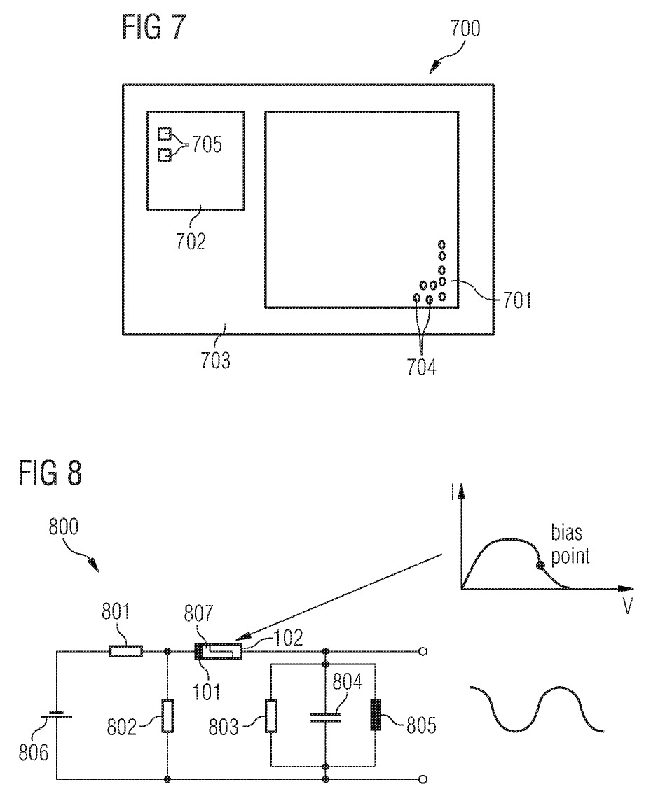

FIG. 7 shows an integrated circuit 700 according to one embodiment of the present invention. The integrated circuit 700 includes a memory array 701 and a controlling circuit 702, wherein the memory array 701 and the controlling circuit 702 are both located on the same chip 703. The memory array 701 includes a plurality of solid electrolyte memory cells 704. The controlling circuit 702 includes at least one active element 705 according to the present invention, for example a diode or a switching element. The at least one active element 705 includes a reactive electrode 101, an inert electrode 102 and a solid electrolyte 103 disposed between the reactive electrode 101 and the inert electrode 102. The solid electrolyte 103 of the at least one active element 705 has a negative differential resistance. The architecture of the at least one active element 705 may, for example, correspond to that of the active element 200 shown in FIGS. 2a and 2b. Further, the architecture of the solid electrolyte memory cells 704 may, for example, correspond to that of the active element 200 shown in FIGS. 2a and 2b. One effect of this is that the at least one active element 705 and the solid electrolyte memory cells 704 can be (at least partly) manufactured using the same manufacturing processes. Thus, the manufacturing process can be reduced.

Although the integrated circuit 700 includes a memory device, it is to be understood that the principles of the present invention can be applied to arbitrary integrated circuits, i.e., also to integrated circuits which do not include any memory devices, for example, pure logic circuits. The embodiments of the active element according to the present invention can be used in any kind of circuit.

FIG. 8 shows a further integrated circuit according to an embodiment of the present invention. An integrated circuit 800 includes an LC-circuit having a first resistance 801, a second resistance 802 and a third resistance 803. The integrated circuit 800 further includes a capacitor 804 and an inductance 805 connected in parallel to the third resistance 803. The integrated circuit 800 further includes a power supply 806 and an active element 807. The active element 807 may, for example, show the same architecture as that of the active element 200 shown in FIGS. 2a and 2b. Normally, the alternating current flowing through the LC-circuit consisting of inductance 805 and capacitor 804 is reduced in its strength due to resistances within the integrated circuit 800 (especially resistance 803) which cannot be avoided. However, due to the active element 807, the oscillation of the current flowing through the inductance 805 is manipulated such that an un-damped current oscillation is obtained, as shown in the current/voltage diagram in the right part of FIG. 8, the active element 807 amplifies the current on the part of the current/voltage curve having a negative gradient. This is achieved by the negative differential resistance of the active element 807 and by biasing the operating point of the active element 807 due to appropriate chosen values for the first resistance 801 and the second resistance 802. In this way, the active element 807 operates similar to a tunnel-diode. The integrated circuit 800 may, for example, be realized as an on-chip oscillator or amplifier.

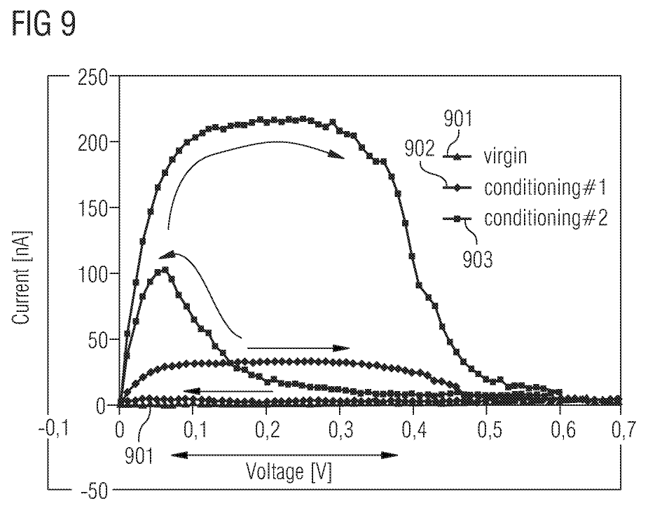

FIG. 9 shows a current/voltage diagram of an active element according to one embodiment of the present invention.

A current/voltage curve 901 denotes an active element having similar characteristics as that of a known solid electrolyte memory cell. Current/voltage curve 902 denotes a current/voltage curve of an active element having similar characteristics as that of a known solid electrolyte memory cell, but with a higher saturation of metallic material within the solid electrolyte block. Current/voltage curve 903 denotes the current/voltage curve of an active element having similar characteristics as that of a known solid electrolyte memory cell, but having a still higher saturation of metallic material within its solid electrolyte block.

The following can be derived from FIG. 9, the higher the saturation of metallic material within the ion conductor block, the higher the negative thermal resistance of the active element. The arrows within FIG. 9 pointing to the right indicate that the voltage is increased, whereas the arrows of FIG. 9 pointing to the left indicate that the voltage is reduced. Different current/voltage curves are obtained for the same active element when increasing the voltage from zero to a particular voltage value, and when decreasing the voltage from that voltage value back to the voltage value zero.

Thus, the oversaturation of metallic material (for example, silver) yields reverse operation with NDR. The characteristics of the active elements characterized by FIG. 9 can be compared to the characteristics of an ESAKI diode (tunnel diode). In this way, active elements, which are biased in the NDR regime, are obtained. Effects of such active elements are low power operation, the integration of a logic circuit and a digital circuit into the same process, and different operating conditions/parameters with respect to standard devices like tunnel diodes resulting in differences concerning achievable oscillation frequencies, gain factors and electrical noise of the circuitry.

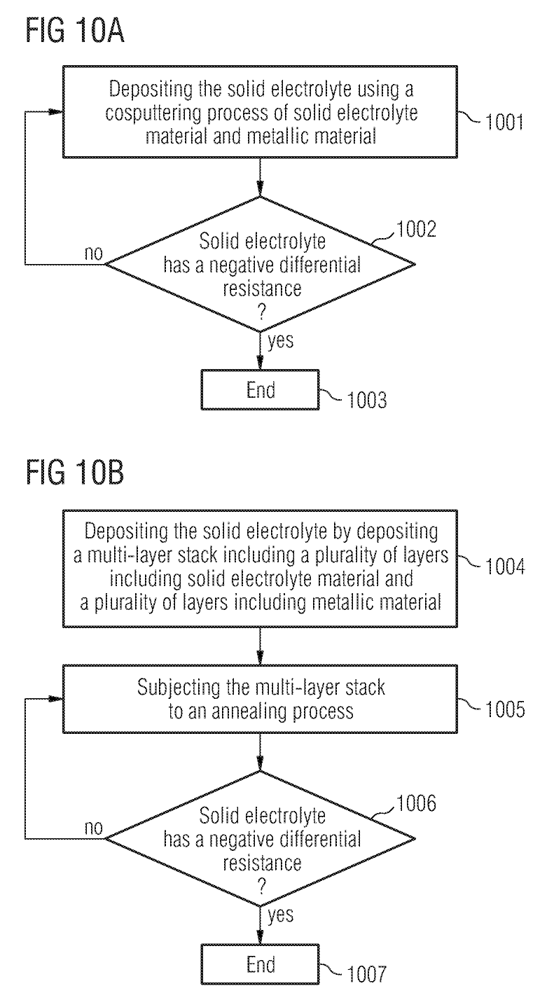

FIG. 10a shows a method of manufacturing an active element according to one embodiment of the present invention. In a first process 1001, solid electrolyte is deposited using a co-sputtering process of solid electrolyte material and metallic material. In a second process 1002, it is determined whether the solid electrolyte, due to the thermal annealing process, already has a negative differential resistance. If the solid electrolyte already has a negative differential resistance, the method is terminated in a third process 1003. Otherwise, the first process 1001 is repeated.

FIG. 10b shows a method of manufacturing an active element according to one embodiment of the present invention. In a first process 1004, a multi-layer stack is deposited including a plurality of layers including solid electrolyte material and a plurality of layers including metallic material. In a second process 1005, the multi-layer stack is subjected to an annealing process. In a third process 1006, it is determined whether the solid electrolyte, due to the thermal annealing process, already has a negative differential resistance. If the solid electrolyte already has a negative differential resistance, the method is terminated in a fourth process 1007. Otherwise, the second process 1005 is repeated.

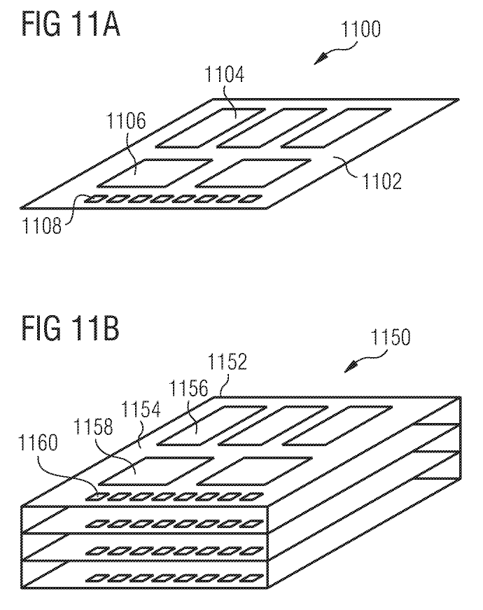

As shown in FIGS. 11a and 11b, in some embodiments, devices such as those described herein may be used in modules. In FIG. 11a, a module 1100 is shown, on which one or more active elements or integrated circuits 1104 according to embodiments of the present invention are arranged on a substrate 1102. The module 1100 may also include one or more electronic devices 1106, which may include memory, processing circuitry, control circuitry, addressing circuitry, bus interconnection circuitry, or other circuitry or electronic devices that may be combined on a module with the active elements or integrated circuits 1104. Additionally, the module 1100 includes multiple electrical connections 1108, which may be used to connect the module 1100 to other electronic components, including other modules.

As shown in FIG. 11b, in some embodiments, these modules may be stackable, to form a stack 1150. For example, a stackable module 1152 may contain one or more devices 1156, arranged on a stackable substrate 1154. The device 1156 contains active elements in accordance with an embodiment of the invention. The stackable module 1152 may also include one or more electronic devices 1158, which may include memory, processing circuitry, control circuitry, addressing circuitry, bus interconnection circuitry, or other circuitry or electronic devices that may be combined on a module with a device, such as the device 1156. Electrical connections 1160 are used to connect the stackable module 1152 with other modules in the stack 1150, or with other electronic devices. Other modules in the stack 1150 may include stackable memory modules, similar to the stackable module 1152 described above, or other types of stackable modules, such as stackable processing modules, control modules, communication modules, or other modules containing electronic components.

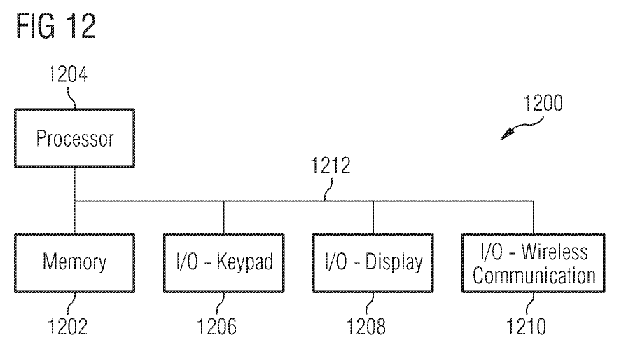

In accordance with some embodiments of the invention, devices that include integrated circuits or active elements as described herein may be used in a variety of applications or systems, such as the illustrative computing system shown in FIG. 12. The computing system 1200 includes integrated circuits or active elements 1202. The system also includes a processing apparatus 1204, such as a microprocessor or other processing device or controller, as well as input and output apparatus, such as a keypad 1206, display 1208, and/or wireless communication apparatus 1210. The device 1202, processing apparatus 1204, keypad 1206, display 1208 and wireless communication apparatus 1210 are interconnected by a bus 1212.

The wireless communication apparatus 1210 may have the ability to send and/or receive transmissions over a cellular telephone network, a WiFi wireless network, or other wireless communication network. It will be understood that the various input/output devices shown in FIG. 12 are merely examples. Integrated circuits or active elements in accordance with embodiments of the invention may be used in a variety of systems. Alternative systems may include a variety input and output devices, multiple processors or processing apparatus, alternative bus configurations, and many other configurations of a computing system. Such systems may be configured for general use, or for special purposes, such as cellular or wireless communication, photography, playing music or other digital media, or any other purpose now known or later conceived to which an electronic device or computing system including memory may be applied. The computing system may, for example, be an amplifier, frequency converter, oscillator, and so on.

In the following description, further aspects of the invention will be explained.

Memory cells including a solid electrolyte material are well known as programmable metallization memory cells (PMC memory cells). Memory devices including such PMC memory cells are known as conductive bridging random access memory devices (CBRAM). Storing of different states in a PMC memory cell is based on the resistance change induced by the development or diminishing of a conductive path in the electrolyte material between electrodes.

CBRAM is one of the promising emerging memory technologies and many research groups and even semiconductor companies are working in this field since several years. A lot of the work is currently focused on memory applications and/or switchable metallic links for programmable logic.

According to one embodiment of the present invention, the same basic set-up using solid electrolyte material and suitable electrodes can open the path to a completely different class of applications. According to one embodiment of the present invention, a new mode of operation for conductive bridging junction (CBJ) cells is described enabling novel applications like amplifier, oscillator, and frequency generator. Moreover, these new devices can work as stand-alone and are also suitable for and needed in a controller/logic unit as part of a memory device.

The embodiments according to the present invention are usable in a large variety of technical fields. According to one embodiment of the present invention, the common electrical property utilized is an IV-characteristic with a branch of negative differential resistance (NDR). This enables operations like amplifiers, frequency converter, oscillators, and so on.

For these applications, devices like Tunnel-diode (Esaki-diode), IMPATT-diode, or BARITT-diode may be used. However, these approaches show some disadvantages. The diodes are only part of the circuitry designed to deliver the desired functionality (amplification, conversion, etc.). The diodes are available as discrete devices making the set-up more complex and large. Only limited parameter space is available for the specific devices with respect to frequency range, noise, and/or power. NDR-devices are based on different technologies compared to the technology for the main circuit they are designed for.

One embodiment of the present invention is based on CB (conductive bridging) junction cells (CBJ) as well known from memory applications currently under investigation. Modifications are described which lead to the occurrence of NDR-branches in the IV-characteristic. The utilization of this novel effect by different operation modes opens a path to the aforementioned applications. Linked to the use of CBJ for these applications are some effects, such as: completely new applications for CBJ, and extended parameter space for the applications (frequency, power, noise) due to the differing detailed electrical performance compared to known techniques. Moreover, these types of devices are used in a variety of technical fields. According to one embodiment of the present invention, a path to integrate the device in the circuitry on a chip is shown. This means, either the expensive and uncomfortable use of discrete devices can be avoided, or new integration options evolve. For example, memory devices need an oscillator and/or amplifier. According to one embodiment of the present invention, CBJ can be used within the memory array as storage elements as well as in the logic part using the same technology.

According to one embodiment of the present invention, a CBJ cell consisting of electrolyte material (GeSe, GeS, AgS, AgSe) is sandwiched between two suitable electrodes. In the virgin state, no metallic link is formed and the CBJ is in the high-ohmic state as used for memory applications. Subsequently the cell is treated in a special way to produce the desired NDR-characteristic. A temperature treatment may be carried out to dissolve a large amount of metallic clusters (material from one electrode, Ag, Cu) in the electrolyte. A high forward biased stress may be applied to drive a large amount of metallic ions from one electrode into the electrolyte and deposit as metallic clusters, for example, close to the opposite electrode (inert, W, Ni, Ti, and nitrides). According to one embodiment of the present invention, at least the majority of the voids are located close to the inert electrode. A deposition of metallic clusters may be carried out during the processing of the cell/deposition of the electrolyte layer, for example, by co-sputtering electrode material.

According to one embodiment of the present invention, the idea for the underlying effect and the observed electrical behaviour is as follows: accompanied with this treatment is the formation of permanent voids in the electrolyte material filled with metallic clusters. Thus, metallic links are formed leaving the CBJ in the low-ohmic state at zero bias condition. Applying a reverse bias (with respect to normal WRITE operation in memory applications, i.e., negative voltage at anode) drives metallic material back into the chalcogenide or back to the anode, thus the resistance is increased again. Removing the bias results in a spontaneous refilling of the voids with metallic material again. This yields a hysteresis behaviour with a well-pronounced NDR characteristic.

According to one embodiment of the present invention, during operation of the CBJ, the cell has to be biased in the NDR regime. Signal gain is possible and the strong non-linear characteristic enables un-damping, frequency conversion, and mixing. The speed of operation as well as the other electrical parameters like gain factors are controlled by the movement of the metallic material inside the clusters and can be tuned by design/technological parameters of the cell, thickness of electrolyte, mobility of metallic material, etc.

As used herein, the terms “connected” and “coupled” are intended to include both direct and indirect connection and coupling, respectively.

While the invention has been particularly shown and described with reference to specific embodiments, it should be understood by those skilled in the art of various changes in form and detail maybe made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. An integrated circuit comprising an active element, the active element comprising:
a reactive electrode;
an inert electrode; and
a solid electrolyte disposed between the reactive electrode and the inert electrode, the solid electrolyte having a negative differential resistance.

2. The integrated circuit according to claim 1, wherein the solid electrolyte includes permanent existing voids that are at least partly filled with metallic material.

3. The integrated circuit according to claim 2, wherein the voids are arranged such that metallic material is driven out of the voids when an external voltage is applied between the reactive electrode and the inert electrode, or when an external voltage applied between the reactive electrode and the inert electrode exceeds a corresponding driving voltage threshold value.

4. The integrated circuit according to claim 2, wherein the voids are arranged such that metallic material is driven out of the solid electrolyte into the voids when an external voltage applied between the reactive electrode and the inert electrode vanishes, or when an external voltage applied between the reactive electrode and the inert electrode falls below a corresponding driving voltage threshold value.

5. The integrated circuit according to claim 3, wherein the external voltage used for driving the metallic material out of the voids ranges from 0.1V to 2V.

6. The integrated circuit according to claim 2, wherein the metallic material forms metallic clusters within the voids.

7. The integrated circuit according to claim 2, wherein the voids have diameters ranging from 5 nm to 1 μm.

8. The integrated circuit according to claim 2, wherein the metallic material and the reactive electrode comprise the same material or consist of the same material.

9. The integrated circuit according to claim 1, wherein the solid electrolyte comprises or consists of chalcogenide.

10. The integrated circuit according to claim 1, wherein the reactive electrode comprises or consists of silver or copper.

11. The integrated circuit according to claim 2, wherein the metallic material comprises or consists of silver or copper.

12. The integrated circuit according to claim 1, wherein the active element is a diode or a transistor.

13. The integrated circuit according to claim 1, wherein the integrated circuit comprises an amplifier, a frequency converter or an oscillator.

14. A method of operating an integrated circuit comprising an active element having a resistance, the active element comprising a reactive electrode, an inert electrode and a solid electrolyte disposed between the reactive electrode and the inert electrode, the solid electrolyte having a negative differential resistance, the method comprising:
increasing the resistance of the active element by increasing an external voltage applied between the reactive electrode and the inert electrode; and/or
decreasing the resistance of the active element by decreasing an external voltage applied between the reactive electrode and the inert electrode.

15. The method according to claim 14, wherein, in order to increase the resistance of the active element, metallic material is driven out of permanent existing voids of the solid electrolyte by increasing the strength of an external voltage applied between the reactive electrode and the inert electrode.

16. The method according to claim 14, wherein, in order to decrease the resistance of the active element, metallic material is driven into permanent existing voids of the solid electrolyte by decreasing the strength of an external voltage applied between the reactive electrode and the inert electrode.

17. The method according to claim 15, wherein the external voltage used for driving the metallic material out of the voids ranges from 0.1V to 2V.

18. The method according to claim 16, wherein the external voltage used for driving the metallic material into the voids ranges from 0V to 0.3V.

19. A method of manufacturing an integrated circuit comprising an active element, the method comprising:
subjecting a composite structure to a thermal annealing process, the composite structure comprising a reactive electrode, an inert electrode and a solid electrolyte disposed between the reactive electrode and the inert electrode, the thermal annealing process being carried out until the solid electrolyte has a negative differential resistance.

20. The method according to claim 19, wherein parameters of the thermal annealing process are chosen such that permanent existing voids are formed within the solid electrolyte, the voids being filled with metallic material, which, due to the thermal annealing process, is driven out of the reactive electrode into the solid electrolyte.

21. The method according to claim 19, wherein the thermal annealing process is carried out at temperatures of about 300° C. to about 500° C.

22. The method according to claim 19, wherein the thermal annealing process is carried out for a duration of about 10 minutes to 2 hours.

23. A method of manufacturing an integrated circuit comprising an active element, the method comprising:
applying a voltage between the reactive electrode and the inert electrode of a composite structure comprising a reactive electrode, an inert electrode and a solid electrolyte disposed between the reactive electrode and the inert electrode,
the application of the voltage being carried out until the solid electrolyte has a negative differential resistance.

24. The method according to claim 23, wherein voltage is applied until permanent existing voids are formed within the solid electrolyte, the voids being filled with metallic material that, due to the application of the voltage, is driven out of the reactive electrode into the solid electrolyte.

25. The method according to claim 23, wherein the application of the voltage is carried out at voltages above 0.3V with a current limitation of 10 μA to 1 mA.

26. A method of manufacturing an integrated circuit comprising an active element comprising a reactive electrode, an inert electrode and a solid electrolyte disposed between the reactive electrode and the inert electrode, the method comprising:
depositing the solid electrolyte using a co-sputtering process of solid electrolyte material and metallic material.

27. The method according to claim 26, further comprising, after depositing the solid electrolyte, subjecting the solid electrolyte to an annealing process.

28. A method of manufacturing an integrated circuit comprising an active element comprising a reactive electrode, an inert electrode and a solid electrolyte disposed between the reactive electrode and the inert electrode, the method comprising:
depositing the solid electrolyte by depositing a multi-layer stack comprising a plurality of layers comprising solid electrolyte material and a plurality of layers comprising metallic material; and
subjecting the multi-layer stack to an annealing process.

29. An active element, comprising:
a reactive electrode;
an inert electrode; and
a solid electrolyte disposed between the reactive electrode and the inert electrode, wherein the solid electrolyte of the active element has a negative differential resistance.

30. A memory module, comprising at least one active element, the active element comprising a reactive electrode, an inert electrode and a solid electrolyte disposed between the reactive electrode and the inert electrode, wherein the solid electrolyte of the active element has a negative differential resistance.

31. The memory module according to claim 30, wherein the memory module is stackable.

32. A computing system comprising:
a processing apparatus;
an input apparatus coupled to the processing apparatus;
an output apparatus coupled to the processing apparatus; and
an active element coupled to the processing apparatus, the active element comprising a reactive electrode, an inert electrode and a solid electrolyte disposed between the reactive electrode and the inert electrode, the solid electrolyte having a negative differential resistance.

33. The computing system according to claim 32, wherein at least one of the input apparatus and/or the output apparatus comprises a wireless communication apparatus.
